(19) United States
(12) Patent Application Publication
(10) Pub. No.: US 2024/0418836 A1
(43) Pub. Date: Dec. 19, 2024

(54) READOUT ARCHITECTURES FOR ERROR REDUCTION IN INDIRECT TIME-OF-FLIGHT SENSORS

(71) Applicant: OMNIVISION TECHNOLOGIES, INC., Santa Clara, CA (US)

(72) Inventors: Zheng Yang, San Jose, CA (US); Andreas Suess, San Jose, CA (US)

(21) Appl. No.: 17/512,988

(22) Filed: Oct. 28, 2021

(51) Int. Cl. G01S 7/4863; G01S 7/4865; G01S 17/26; H01L 27/146; H04N 25/771

(52) U.S. Cl. CPC G01S 7/4863; G01S 7/4865; G01S 17/26; H01L 27/14612; H04N 25/771

(57) ABSTRACT

A time-of-flight pixel array includes first transistors to transfer a first phase portion of charge from photodiodes responsive to reflected modulated light during a first subframe, and a second phase portion of the charge during a second subframe. The second phase is an inverted first phase. Second transistors transfer the second phase portion of the charge during the first subframe, and the first phase portion of the charge during the second subframe. Third transistors transfer a third phase portion of the charge during the first subframe, and a fourth phase portion of the charge during the second subframe. The fourth phase is an inverted third phase. The third phase is ninety degrees out of phase with the first phase. Fourth transistors transfer the fourth phase portion of the charge during the first subframe, and the third phase portion of the charge during the second subframe.

### BACKGROUND INFORMATION

### Field of the Disclosure

This disclosure relates generally to image sensors, and in particular but not exclusively, relates to time-of-flight sensors.

### Background

Interest in three dimensional (3D) cameras is increasing as the popularity of 3D applications continues to grow in areas such as imaging, movies, games, computers, user interfaces, facial recognition, object recognition, augmented reality, and the like. A typical passive way to create 3D images is to use multiple cameras to capture stereo or multiple images. Using the stereo images, objects in the images can be triangulated to create the 3D image. One disadvantage with this triangulation technique is that it is difficult to create 3D images using small devices because there must be a minimum separation distance between each camera in order to create the 3D images. In addition, this technique is complex and therefore requires significant computer processing power in order to create the 3D images in real time.

For applications that require the acquisition of 3D images in real time, active depth imaging systems based on time-of-flight measurements are sometimes utilized. Time-of-flight cameras typically employ a light source that directs light at an object, a sensor that detects the light that is reflected from the object, and a processing unit that calculates the distance to the object based on the round-trip time it takes for the light to travel to and from the object.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 is a block diagram that shows one example of a time-of-flight light sensing system in accordance with the teachings of the present invention.

FIG. 2 is a timing diagram that shows an example of light pulses emitted from a light source relative to the receipt of the reflected light pulses and measurements using various phase shifts in an example time-of-flight sensing system accordance with the teachings of the present invention.

FIG. 3 is a schematic illustrating one example of a time-of-flight pixel circuit in accordance with the teachings of the present invention.

FIG. 4A is a schematic illustrating one example of time-of-flight pixel circuits included in a time-of-flight pixel array of a time-of-flight sensing system in accordance with the teachings of the present invention.

FIG. 4B is a schematic illustrating another example of time-of-flight pixel circuits included in a time-of-flight pixel array of a time-of-flight sensing system in accordance with the teachings of the present invention.

FIG. 5 is a schematic illustrating yet another example of time-of-flight pixel circuits included in a time-of-flight pixel array of a time-of-flight sensing system in accordance with the teachings of the present invention.

FIG. 6 is a schematic illustrating still another example of a time-of-flight pixel circuit included in a time-of-flight pixel array of a time-of-flight sensing system in accordance with the teachings of the present invention.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention. In addition, common but well-understood elements that are useful or necessary in a commercially feasible embodiment are often not depicted in order to facilitate a less obstructed view of these various embodiments of the present invention.

### DETAILED DESCRIPTION

Examples directed to various embodiments of a time-of-flight pixel circuits included in pixel arrays of time-of-flight sensing systems are described herein. In the following description, numerous specific details are set forth to provide a thorough understanding of the examples. One skilled in the relevant art will recognize, however, that the techniques described herein can be practiced without one or more of the specific details, or with other methods, components, materials, etc. In other instances, well-known structures, materials, or operations are not shown or described in detail in order to avoid obscuring certain aspects.

Reference throughout this specification to “one example” or “one embodiment” means that a particular feature, structure, or characteristic described in connection with the example is included in at least one example of the present invention. Thus, the appearances of the phrases “in one example” or “in one embodiment” in various places throughout this specification are not necessarily all referring to the same example. Furthermore, the particular features, structures, or characteristics may be combined in any suitable manner in one or more examples.

Spatially relative terms, such as “beneath,” “below,” “over,” “under,” “above,” “upper,” “top,” “bottom,” “left,” “right,” “center,” “middle,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is rotated or turned over, elements described as “below” or “beneath” or “under” other elements or features would then be oriented “above” the other elements or features. Thus, the exemplary terms “below” and “under” can encompass both an orientation of above and below. The device may be otherwise oriented (rotated ninety degrees or at other orientations) and the spatially relative descriptors used herein interpreted accordingly. In addition, it will also be understood that when an element is referred to as being “between” two other elements, it can be the only element between the two other elements, or one or more intervening elements may also be present.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

As will be discussed, various examples of indirect time-of-flight (e.g., iTOF) sensing systems are disclosed in which modulated light is emitted from a light source to an object, which is then reflected from the object back to a time-of-flight pixel array included in the time-of-flight sensing system. The object distance is determined in response to the measured phase of the modulation sensed by the time-of-flight pixel circuits, which may be used to yield a 3D frame.

As will be discussed, various examples of the time-of-flight pixel circuits are modulated with 0°/180° and 180°/0° phase modulation signals as well as with 90°/270° and 270°/90° phase modulation signals in two subframes when sensing the reflected modulated light from the object. By modulating the time-of-flight pixel circuits with the opposing phases of the 0°/180° and 180°/0° phase modulations signals as well as with the opposing phases of the 90°/270° and 270°/90° phase modulation signals in the two subframes, offset errors as well as dark current errors in the time-of-flight pixel circuits are canceled or removed in accordance with the teachings of the present invention. In the various examples, the 0°, 90°, 180°, and 270° phase modulation signals have the same frequency as the modulated light that is emitted to the object from the light source of the time-of-flight sensing system to realize homodyne detection by the indirect time-of-flight sensor. Employing the different phases in the phase modulation signals allows to reconstruction of the encoded distance.

It is noted that phases that are increments of 360° apart cannot be distinguished, which consequently results in ambiguities in the measurements. As a result, the modulation frequency of the phase modulation signals is chosen not to exceed a maximum modulation frequency in order to accommodate a desired depth range. However, a tradeoff is that increasing the modulation frequency improves precision.

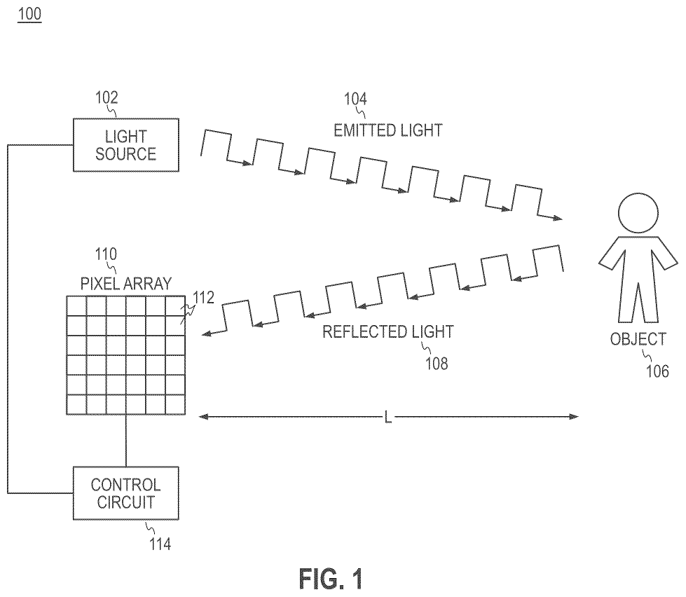

To illustrate, FIG. 1 is a block diagram that shows one example of a time-of-flight light sensing system 100 in accordance with the teachings of the present invention. In the depicted example, time-of-flight light sensing system 100 is a 3D camera that calculates image depth information of a scene (e.g., object 106) based on indirect time-of-flight (e.g., iToF) measurements with an image sensor that includes pixel array 110. In some examples, it is appreciated that although time-of-flight light sensing system 100 is capable of sensing 3D images, time-of-flight light system 100 may also be utilized to capture 2D images. In various examples, time-of-flight light sensing system 100 may also be utilized to capture high dynamic range (HDR) images.

As shown in the depicted example, time-of-flight light sensing system 100 includes light source 102 that is synchronized with a time-of-flight sensor that includes a time-of-flight pixel array 110, which includes a plurality of time-of-flight pixel circuits 112, and a control circuit 114 that is coupled to control and synchronize the time-of-flight pixel array 110 and light source 102.

As shown in the example, light source 102 and time-of-flight pixel array 110 are positioned at a distance L from object 106. Light source 102 is configured to emit light 104 towards object 106. Reflected light 108 is directed back from object 106 to time-of-flight pixel array 110 as shown. It is noted that time-of-flight pixel array 110 and control circuit 114 are represented as separate components in FIG. 1 for explanation purposes. However, it is appreciated that time-of-flight pixel array 110 and components of control circuit 114 may be integrated onto a same integrated circuit chip or wafer in a non-stacked standard planar sensor.

Continuing with the depicted example, each time-of-flight pixel circuit 112 of time-of-flight pixel array 110 determines depth information for a corresponding portion of object 106 such that a 3D image of object 106 can be generated. As will be discussed in greater detail below, depth information is determined by modulating the transfer gates of each time-of-flight pixel circuit 112 with 0°/180° and 180°/0° phase modulation signals as well as with 90°/270° and 270°/90° phase modulation signals in two subframes to measure the delay/phase difference between emitted light 104 and the received reflected light 108 to indirectly determine a round-trip time for light to propagate from light source 102 to object 106 and back to the time-of-flight pixel array 110 of time-of-flight light sensing system 100. The depth information may be based on an electric signal generated by the photodiode included in each time-of-flight pixel circuit 112, which is subsequently transferred to a storage node and read out.

As illustrated, light source 102 is configured to emit light 104 to the object 106 over a distance L. The emitted light 104 is then reflected from the object 106 as reflected light 108 (e.g., reflected light waves/pulses), some of which propagates towards the time-of-flight pixel array 110 of time-of-flight light sensing system 100 over the distance L and is incident upon the time-of-flight pixel circuits 112 of time-of-flight pixel array 110 as image light. Each time-of-flight pixel circuit 112 included in the time-of-flight pixel array 110 includes a photodetector (e.g., one or more photodiodes, avalanche photodiodes, or single-photon avalanche diodes, or the like) to detect the reflected light 108 and convert the reflected light 108 into an electric signal (e.g., electrons, image charge, etc.).

As shown in the depicted example, the round-trip time for emitted light 104 to propagate from light source 102 to object 106 and then be reflected back to time-of-flight pixel array 110 can be used to determine the distance L using the following relationships in Equations (1) and (2) below:

$${T}_{TOF} = \frac{2 L}{c} \qquad ( 1 )$$

$$L = \frac{{T}_{TOF} \cdot c}{2} \qquad ( 2 )$$

where c is the speed of light, which is approximately equal to 3×10⁸ m/s, and TTOF corresponds to the round-trip time, which is the amount of time that it takes for the light to travel to and from the object 106 as shown in FIG. 1. Accordingly, once the round-trip time is known, the distance L may be calculated and subsequently used to determine depth information of object 106.

As shown in the depicted example, control circuit 114 is coupled to time-of-flight pixel array 110 and light source 102, and includes logic and memory that when executed causes time-of-flight light sensing system 100 to perform operations for determining the round-trip time. Determining the round-trip time may be based on, at least in part, timing signals generated by control circuit 114. For indirect time-of-flight (indirect time-of-flight) measurements, the timing signals are representative of the delay/phase difference between the light waves/pulses of when the light source 102 emits light 104 and when the photodetectors in time-of-flight pixel circuits 112 detect the reflected light 108.

In some examples, time-of-flight light sensing system 100 may be included in a device (e.g., a mobile phone, a tablet, a camera, etc.) that has size and power constraints determined, at least in part, based on the size of the device. Alternatively, or in addition, time-of-flight light sensing system 100 may have specific desired device parameters such as frame rate, depth resolution, lateral resolution, etc.

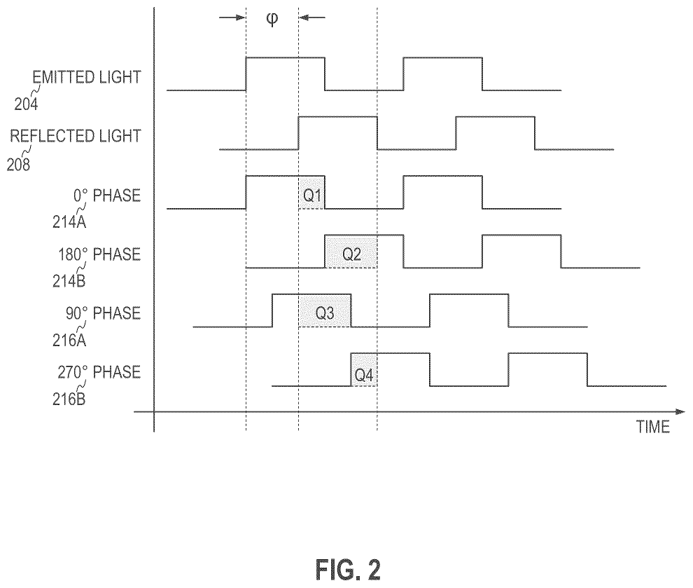

FIG. 2 is a timing diagram that illustrates the timing relationship between example light pulses emitted from a light source relative to the receipt of the reflected light pulses and measurements using various phase shifts in an example time-of-flight imaging system accordance with the teachings of the present invention. Specifically, FIG. 2 shows emitted light 204, which represents the modulated light pulses that are emitted from the light source 102 to the object 106, and corresponding pulses reflected light 208, which represents the reflected light pulses that are back-reflected from the object 106 and received by the time-of-flight pixel circuits 112 in time-of-flight pixel array 110 of FIG. 1.

The example depicted in FIG. 2 also illustrates measurement pulses of the phase modulation signals including a 0° phase modulation signal 214A (e.g., a first phase modulation signal) and a 180° phase modulation signal 214B (e.g., a second phase modulation signal), as well as measurement pulses including a 90° phase modulation signal 216A (e.g., a third phase modulation signal) and a 270° phase modulation signal 216B (e.g., a fourth phase modulation signal), which as shown are all phase-shifted relative to the phase of the pulses of emitted light 204. In addition, it is appreciated that in the depicted example the 180° phase modulation signal 214B is an inverted 0° phase modulation signal 214A, that the 90° phase modulation signal 216A is ninety degrees out of phase with the 0° phase modulation signal 214A, and that the 270° phase modulation signal 216B is an inverted 90° phase modulation signal 216A.

FIG. 2 also shows that the 0° phase modulation signal 214A and 180° phase modulation signal 214B, as well as the 90° phase modulation signal 216A and 270° phase modulation signal 216B pulses are all modulated at the same frequency as the modulated emitted light 204 and reflected light 208 to realize homodyne detection of the reflected light 208 in accordance with the teachings of the present invention. Utilizing the different phases for the example measurement pulses as shown allows reconstruction of the encoded distance in two subframes in accordance with the teachings of the present invention.

As will be discussed, the 0° phase modulation signal 214A and 180° phase modulation signal 214B, as well as the 90° phase modulation signal 216A and 270° phase modulation signal 216B pulses correspond to the switching or modulation of transfer transistors that are included in the time-of-flight pixel circuits 112 of time-of-flight pixel array 110. In operation, the modulation of the transfer transistors in the time-of-flight pixel circuits 112 of time-of-flight pixel array 110 can be used to measure the charge that is photogenerated in the one or more photodiodes that are included the time-of-flight pixel circuits 112 in response to the reflected light 208 to determine the delay or phase difference φ between the pulses of emitted light 204 and the corresponding pulses of reflected light 208.

For instance, the example illustrated in FIG. 2 shows that a first phase portion of charge Q1 is photogenerated by the pulses of 0° phase modulation signal 214A and that a second phase portion of charge Q2 is photogenerated by the pulses of 180° phase modulation signal 214B in response to reflected light 208. Similarly, a third phase portion of charge Q3 is photogenerated by the pulses of 90° phase 216A and a fourth phase portion of charge Q4 is photogenerated by the pulses of 270° phase modulation signal 216B in response to reflected light 208. As will be discussed in greater detail below, the measurements of four phase portions of charge Q1, Q2, Q3, and Q4 can then be used to measure the delay or phase difference φ between the emitted light 204 and the reflected light 208, and therefore the time of flight T_{TOF} of light from the light source 102 to the object 106 and then back to the time-of-flight pixel array 110 in accordance with the teachings of the present invention.

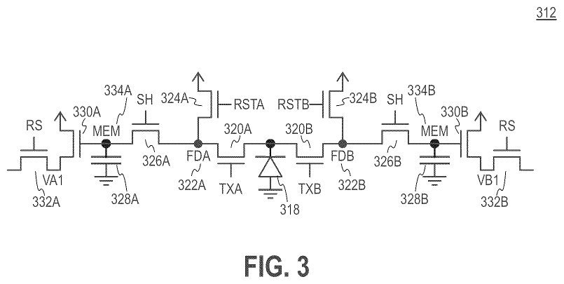

FIG. 3 is a schematic illustrating one example of a time-of-flight pixel circuit 312 included in a pixel array of a time-of-flight sensor in accordance with the teachings of the present invention. It is appreciated that the time-of-flight pixel circuit 312 of FIG. 3 may be an example of one of the time-of-flight pixel circuits 112 included in pixel array 110 shown in FIG. 1, and that similarly named and numbered elements described above are coupled and function similarly below.

As shown in the example depicted in FIG. 3, time-of-flight pixel circuit 312 includes a photodiode 318 configured to photogenerate charge in response to incident light. In one example, the light that is incident on photodiode 318 is the reflected modulated light 108 that is reflected from an object 106 as described in FIG. 1. A first floating diffusion FDA 322A is configured to store a first portion of charge photogenerated in the photodiode 318, and second floating diffusion FDB 322B is configured to store a second portion of charge photogenerated in the photodiode 318.

A first transfer transistor 320A is configured to transfer the first portion of charge from the photodiode 318 to the first floating diffusion FDA 322A in response to a first phase modulation signal TXA. In one example, the first phase modulation signal TXA may be an example of one of the phase modulation signals described in FIG. 2. A second transfer transistor 320B is configured to transfer the second portion of charge from the photodiode 318 to the second floating diffusion FDB 322B in response to a second phase modulation signal TXB. In the example, the second phase modulation signal TXB may also be an example of one of the phase modulation signals described in FIG. 2.

For instance, in the various examples, the first phase modulation signal TXA and second phase modulation signal TXB are modulation signals that are 180° out of phase or inverted versions of each other during the two subframes in which the time-of-flight pixel circuit 312 is modulated. For instance, in one example, in a first subframe, the first phase modulation signal TXA may be the 0° phase modulation signal 214A while the second phase modulation signal TXB is therefore the 180° phase modulation signal 214B. In that example, in the second subframe, the first phase modulation signal TXA and the second phase modulated signal TXB are inverted relative to their respective signals in the first subframe. In other words, in that example, in the second subframe, the first phase modulation signal TXA is the 180° phase modulation signal 216B while the second phase modulation signal TXB is the 0° phase modulation signal 214A.

As will be discussed in detail below, by modulating the first and second transfer transistors 320A and 320B with the opposing phases of the 0°/180° and 180°/0° phase modulations signals in the two subframes, offset errors as well as dark current errors in the time-of-flight pixel circuits are canceled or removed in accordance with the teachings of the present invention. In another example, it is appreciated that the first and second transfer transistors 320A and 320B may also be modulated with opposing phases of 90°/270° and 270°/90° phase modulations signals in the two subframes to cancel or remove the offset errors as well as dark current errors in the time-of-flight pixel circuits in accordance with the teachings of the present invention.

In the example, a first storage node MEM 334A is configured to store the first portion of charge from the first floating diffusion FDA 322A through a first sample and hold transistor 326A, and a second storage node MEM 334B is configured to store the second portion of charge from the second floating diffusion FDB 322B through a second sample and hold transistor 326B. In the various examples, the first and second sample and hold transistors 326A and 326B are coupled to be responsive to a sample and hold signal SH.

Continuing with the example depicted in FIG. 3, the first storage node MEM 334A is coupled to a first capacitor 328A and a gate of a first source follower transistor 330A. A first row select transistor 332A is coupled to a source of the first source follower transistor 330A. In the various examples, the first row select transistor 332A may also coupled to a first bitline, through which first output signal information may be read out from pixel circuit 312.

In one example, the output of the first row select transistor 332A may be considered a first tap of the time-of-flight pixel circuit 312 from which the output VAI may be read out. Similarly, the second storage node MEM 334B is coupled to a second capacitor 328B and a gate of a second source follower transistor 330B. A second row select transistor 332B is coupled to a source of the second source follower transistor 330B. In the various examples, the second row select transistor 332B may also coupled to a second bitline, through which a second output signal information may be read out from pixel circuit 312. In one example, the output of the second row select transistor 332B may be considered to be a second tap of the pixel circuit 312 from which the output VB1 may be read out. Thus in the example depicted in FIG. 3, pixel circuit 312 may be considered to be a 2-tap time-of-flight pixel circuit from which outputs VA1 and VB1 may be read out. In the various examples, the first and second row select transistors 332A and 332B are coupled to be responsive to a row select signal RS.

In the various examples, time-of-flight pixel circuit 312 also includes a first reset transistor 324A coupled between a supply rail and the first floating diffusion FDA 322A. In various examples, first reset transistor 324A is configured to reset the first floating diffusion FDA 322A as well the first storage node MEM 334A in response to a first reset signal RSTA. In the example depicted in FIG. 3, the first reset transistor 324A is configured to reset the first storage node MEM 334A through the first sample and hold transistor 326A. In various examples, it is appreciated that first reset transistor 324A may be operated in a way that excess carriers generated by photodiode 318 may be guided to the power supply by first reset transistor 324A or in a way that photosensitivity of photodiode 318 is disabled.

Similarly, time-of-flight pixel circuit 312 also includes a second reset transistor 324B coupled between the supply rail and the second floating diffusion FDB 322B. In various examples, second reset transistor 324B is configured to reset the second floating diffusion FDB 322B as well the second storage node MEM 334B in response to a second reset signal RSTB. In one example, the first reset signal RSTA and the second reset signal RSTB may be the same reset signal. In the example depicted in FIG. 3, the second reset transistor 324B is configured to reset the second storage node MEM 334B through the second sample and hold transistor 326B. In various examples, it is appreciated that second reset transistor 324B may be operated in a way that excess carriers generated by photodiode 318 may be guided to the power supply by second reset transistor 324B or in a way that photosensitivity of photodiode 318 is disabled.

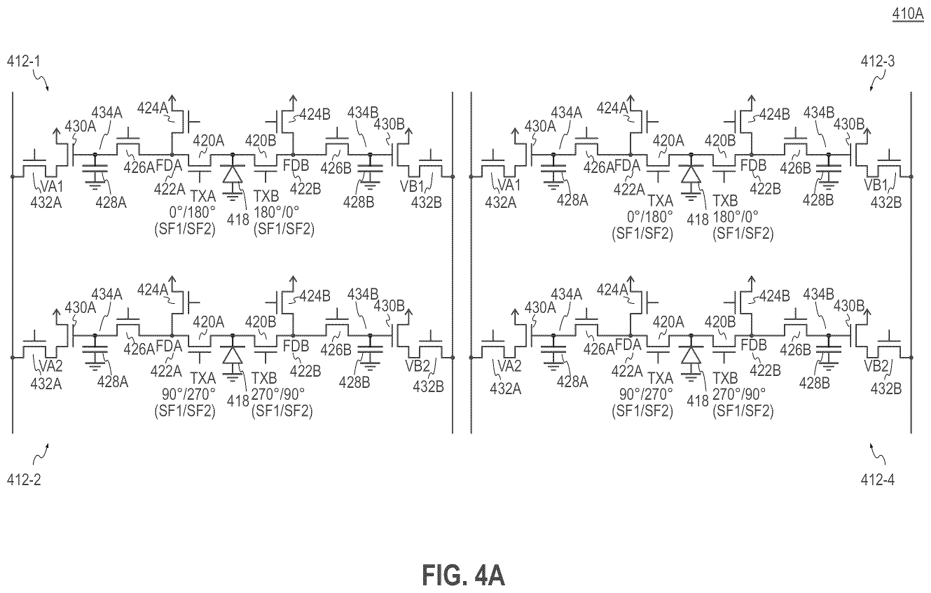

FIG. 4A is a schematic illustrating one example of time-of-flight pixel circuits 412-1, 412-2, 412-3, 412-4 included in a time-of-flight pixel array 410A of a time-of-flight sensing system in accordance with the teachings of the present invention. It is appreciated that the example of time-of-flight pixel circuits 412-1, 412-2, 412-3, 412-4 illustrated in FIG. 4A may be examples of the time-of-flight pixel circuit 312 shown in FIG. 3 or the time-of-flight pixel circuits 112 shown in FIG. 1, and/or that example time-of-flight pixel array 410A illustrated in FIG. 4A may be an example of time-of-flight pixel array 110 shown in FIG. 1, and that similarly named and numbered elements described above are coupled and function similarly below.

It is also appreciated each of the example time-of-flight pixel circuits 412-1, 412-2, 412-3, 412-4 illustrated in FIG. 4A is substantially similar to the time-of-flight pixel circuit 312 shown in FIG. 3. For instance, each of the example time-of-flight pixel circuits 412-1, 412-2, 412-3, 412-4 depicted in FIG. 4A includes a photodiode 418 coupled to first and second transfer transistors 420A and 420B. First and second floating diffusions FDA 422A and FDB 422B are coupled to the first and second transfer transistors 420A and 420B, and first and second reset transistors 424A and 424B are coupled to the respective first and second floating diffusions FDA 422A and FDB 422B. First and second sample and hold transistors 426A and 426B are coupled between the respective first and second floating diffusions FDA 422A and FDB 422B and respective first and second memory nodes 434A and 434B, which are coupled to respective first and second capacitors 428A and 428B. First and second source follower transistors 430A and 430B are coupled to respective first and second memory nodes 434A and 434B, and first and second row select transistors 432A and 432B are coupled between the respective first and second source follower transistors 430A and 430B and respective first and second bitlines, which may also be referred to as first and second output taps of each respective time-of-flight pixel circuit 412-1, 412-2, 412-3, 412-4 from which the outputs (e.g., VA1, VB1, VA2, VB2) may be read out.

In the depicted example, the time-of-flight pixel circuits 412-1, 412-2, 412-3, 412-4 are arranged in rows and columns in the time-of-flight pixel array 410A. For instance, the example depicted in FIG. 4A shows that time-of-flight pixel circuits 412-1 and 412-2 are in the same column and time-of-flight pixel circuits 412-3 and 412-4 are in a neighboring column. Stated in another way, the example depicted in FIG. 4A shows that time-of-flight pixel circuits 412-1 and 412-3 are in the same row and time-of-flight pixel circuits 412-2 and 412-4 are in a neighboring row.

In operation, each of plurality of photodiodes 418 of the time-of-flight pixel circuits 412-1, 412-2, 412-3, 412-4 is configured to generate charge in response to reflected modulated light (e.g., reflected light 108) incident upon the plurality of photodiodes 418. In the example, the photodiode 418 of time-of-flight pixel circuit 412-1 may be considered to be a first photodiode 418 of pixel array 410A. In the example, the transfer transistor 420A of time-of-flight pixel circuit 412-1 may be considered to be a first transfer transistor 420A and the transfer transistor 420B of time-of-flight pixel circuit 412-1 may be considered to be a second transfer transistor 420B of time-of-flight pixel array 410A.

In operation, the first transfer transistor 420A of time-of-flight pixel circuit 412-1 is configured to transfer a first phase portion of the charge (e.g., Q1) from the first photodiode 418 of time-of-flight pixel circuit 412-1 in response to a first phase modulation signal (e.g., 0° phase modulation signal 214A) during a first subframe (e.g., SF1). In the example, the first transfer transistor 420A of time-of-flight pixel circuit 412-1 is configured to transfer a second phase portion of the charge (e.g., Q2) from the first photodiode 418 of time-of-flight pixel circuit 412-1 in response to a second phase modulation signal (e.g., 180° phase modulation signal 214B) during a second subframe (e.g., SF2).

Continuing with the example, the second transfer transistor 420B of time-of-flight pixel circuit 412-1 is configured to transfer the second phase portion of the charge (e.g., Q2) from the first photodiode 418 of time-of-flight pixel circuit 412-1 in response to the second phase modulation signal (e.g., 180° phase modulation signal 214B) during the first subframe (e.g., SF1). In the example, the second transfer transistor 420B of time-of-flight pixel circuit 412-1 is configured to transfer the first phase portion of the charge (e.g., Q1) from the first photodiode 418 of time-of-flight pixel circuit 412-1 in response to the first phase modulation signal (e.g., 0° phase modulation signal 214A) during the second subframe (e.g., SF2).

In the depicted example, the photodiode 418 of time-of-flight pixel circuit 412-2 in the neighboring row may be considered to be a second photodiode 418 of time-of-flight pixel array 410A. Similarly, the transfer transistor 420A of time-of-flight pixel circuit 412-2 may be considered to be a third transfer transistor 420A and the transfer transistor 420B of time-of-flight pixel circuit 412-2 may be considered to be a fourth transfer transistor 420B of time-of-flight pixel array 410A.

In operation, the third transfer transistor 420A of time-of-flight pixel circuit 412-2 is configured to transfer a third phase portion of the charge (e.g., Q3) from the second photodiode 418 of time-of-flight pixel circuit 412-2 in response to a third phase modulation signal (e.g., 90° phase modulation signal 216A) during the first subframe (e.g., SF1). In the example, the third transfer transistor 420A of time-of-flight pixel circuit 412-2 is configured to transfer a fourth phase portion of the charge (e.g., Q4) from the second photodiode 418 of time-of-flight pixel circuit 412-2 in response to a fourth phase modulation signal (e.g., 270° phase modulation signal 216B) during the second subframe (e.g., SF2).

Continuing with the example, the fourth transfer transistor 420B of time-of-flight pixel circuit 412-2 is configured to transfer the fourth phase portion of the charge (e.g., Q4) from the second photodiode 418 of time-of-flight pixel circuit 412-2 in response to the fourth phase modulation signal (e.g., 270° phase modulation signal 216B) during the first subframe (e.g., SF1). In the example, the fourth transfer transistor 420B of time-of-flight pixel circuit 412-2 is configured to transfer the third phase portion of the charge (e.g., Q3) from the second photodiode 418 of time-of-flight pixel circuit 412-2 in response to the third phase modulation signal (e.g., 90° phase modulation signal 216A) during the second subframe (e.g., SF2).

Therefore, it is appreciated that the time-of-flight pixel circuit 412-1 is modulated with 0°/180° phase modulation signals 214A and 214B in a first subframe (e.g., SF1) and then with opposing 180°/0° phase modulation signals 214B and 214A in a second subframe (e.g. SF2). Similarly, it is appreciated that the neighboring time-of-flight pixel circuit 412-2 in the neighboring row is modulated with 90°/270° phase modulations signals 216A and 216B in the first subframe (e.g., SF1) and then with opposing 270°/90° phase modulation signals 216B and 216A in the second subframe (e.g., SF2).

In the example, as depicted in FIG. 4A, it is further appreciated that the time-of-flight pixel circuit 412-3 is shown to be modulated with the same 0°/180° phase modulation signals 214A and 214B in a first subframe (e.g., SF1) and then with the opposing 180°/0° phase modulation signals 214B and 214A in a second subframe (e.g. SF2). Similarly, it is appreciated that the time-of-flight pixel circuit 412-4 in the neighboring row is also modulated with 90°/270° phase modulations signals 216A and 216B in the first subframe (e.g., SF1) and then with opposing 270°/90° phase modulation signals 216B and 216A in the second subframe (e.g., SF2). Therefore, it is appreciated that the time-of-flight pixel circuits 412-1 and 412-3, are modulated with the 0°/180° and 180°/0° phase modulation signals and that the time-of-flight pixel circuits 412-2 and 412-4 with 90°/270° and 270°/90° phase modulation signals in two subframes based on alternating rows of pixel array 410A in the depicted example.

By modulating the time-of-flight pixel circuits 412-1, 412-2, 412-3, 412-4 with the opposing phases of the 0°/180° and 180°/0° phase modulations signals as well as with the opposing phases of the 90°/270° and 270°/90° phase modulation signals in the two subframes as described, offset errors as well as dark current errors in the time-of-flight pixel circuits are canceled or removed in accordance with the teachings of the present invention.

To illustrate, the following relationships regarding the time-of-flight pixel circuits 412-1, 412-2, 412-3, 412-4 of time-of-flight pixel array 410A are given:

$${V}_{SF 1 - A 1} = {V}_{A 1} = {o}_{A 1} + {CG}_{A 1} \cdot ( {Q}_{0} + D {C}_{1} ) \qquad ( 3 )$$

In Equation (3), V_{SF1-A1} represents the voltage V_{A1} at the output tap on the left side of time-of-flight pixel circuit 412-1 during the first subframe SF1, o_{A1} represents the offset error at the output tap on the left side of time-of-flight pixel circuit 412-1, CG_{A1} represents the conversion gain at the output tap on the left side of time-of-flight pixel circuit 412-1, Q₀ represents the 0° phase portion of charge (e.g., Q1), and DC₁ represents the dark current error of time-of-flight pixel circuit 412-1.

$${V}_{SF 1 - B 1} = {V}_{B 1} = {o}_{B 1} + {CG}_{B 1} \cdot ( {Q}_{180} + D {C}_{1} ) \qquad ( 4 )$$

In Equation (4), V_{SF1-B1} represents the voltage V_{B1} at the output tap on the right side of time-of-flight pixel circuit 412-1 during the first subframe SF1, o_{B1} represents the offset error at the output tap on the right side of time-of-flight pixel circuit 412-1, CG_{B1} represents the conversion gain at the output tap on the right side of time-of-flight pixel circuit 412-1, Q₁₈₀ represents the 180° phase portion of charge (e.g., Q2), and DC₁ represents the dark current error of time-of-flight pixel circuit 412-1.

$${V}_{SF 1 - A 2} = {V}_{A 2} = {o}_{A 2} + {CG}_{A 2} \cdot ( {Q}_{90} + D {C}_{2} ) \qquad ( 5 )$$

In Equation (5), V_{SF1-A2} represents the voltage V_{A2} at the output tap on the left side of time-of-flight pixel circuit 412-2 during the first subframe SF1, o_{A2} represents the offset error at the output tap on the left side of time-of-flight pixel circuit 412-2, CG_{A2} represents the conversion gain at the output tap on the left side of time-of-flight pixel circuit 412-2, Q₉₀ represents the 90° phase portion of charge (e.g., Q3), and DC₂ represents the dark current error of time-of-flight pixel circuit 412-2.

$${V}_{SF 1 - B 2} = {V}_{B 2} = {o}_{B 2} + {CG}_{B 2} \cdot ( {Q}_{270} + D {C}_{2} ) \qquad ( 6 )$$

In Equation (6), V_{SF1-B2} represents the voltage V_{B2} at the output tap on the right side of time-of-flight pixel circuit 412-2 during the first subframe SF1, o_{B2} represents the offset error at the output tap on the right side of time-of-flight pixel circuit 412-2, CG_{B2} represents the conversion gain at the output tap on the right side of time-of-flight pixel circuit 412-2, Q₂₇₀ represents the 270° phase portion of charge (e.g., Q4), and DC₂ represents the dark current error of time-of-flight pixel circuit 412-2.

$${V}_{SF 2 - A 1} = {V}_{A 1} = {o}_{A 1} + {CG}_{A 1} \cdot ( {Q}_{180} + D {C}_{1} ) \qquad ( 7 )$$

In Equation (7), V_{SF2-A1} represents the voltage V_{A1} at the output tap on the left side of time-of-flight pixel circuit 412-1 during the second subframe SF2, o_{A1} represents the offset error at the output tap on the left side of time-of-flight pixel circuit 412-1, CG_{A1} represents the conversion gain at the output tap on the left side of time-of-flight pixel circuit 412-1, Q₁₈₀ represents the 180° phase portion of charge (e.g., Q3), and DC₁ represents the dark current error of time-of-flight pixel circuit 412-1.

$${V}_{SF 2 - B 1} = {V}_{B 1} = {o}_{B 1} + {CG}_{B 1} \cdot ( {Q}_{0} + D {C}_{1} ) \qquad ( 8 )$$

In Equation (8), V_{SF2-B1} represents the voltage V_{B1} at the output tap on the right side of time-of-flight pixel circuit 412-1 during the second subframe SF2, o_{B1} represents the offset error at the output tap on the right side of time-of-flight pixel circuit 412-1, CG_{B1} represents the conversion gain at the output tap on the right side of time-of-flight pixel circuit 412-1, Q₀ represents the 0° phase portion of charge (e.g., Q1), and DC₁ represents the dark current error of time-of-flight pixel circuit 412-1.

$${V}_{SF 2 - A 2} = {V}_{A 2} = {o}_{A 2} + {CG}_{A 2} \cdot ( {Q}_{270} + D {C}_{2} ) \qquad ( 9 )$$

In Equation (9), V_{SF2-A2} represents the voltage V_{A2} at the output tap on the left side of time-of-flight pixel circuit 412-2 during the second subframe SF2, o_{A2} represents the offset error at the output tap on the left side of time-of-flight pixel circuit 412-2, CG_{A2} represents the conversion gain at the output tap on the left side of time-of-flight pixel circuit 412-2, Q₂₇₀ represents the 270° phase portion of charge (e.g., Q4), and DC₂ represents the dark current error of time-of-flight pixel circuit 412-2.

$${V}_{SF 2 - B 2} = {V}_{B 2} = {o}_{B 2} + {CG}_{B 2} \cdot ( {Q}_{90} + D {C}_{2} ) \qquad ( 10 )$$

In Equation (10), V_{SF2-B2} represents the voltage V_{B2} at the output tap on the right side of time-of-flight pixel circuit 412-2 during the second subframe SF2, o_{B2} represents the offset error at the output tap on the right side of time-of-flight pixel circuit 412-2, CG_{B2} represents the conversion gain at the output tap on the right side of time-of-flight pixel circuit 412-2, Q₉₀ represents the 90° phase portion of charge (e.g., Q3), and DC₂ represents the dark current error of time-of-flight pixel circuit 412-2.

With the relationships given in Equations (3)-(10), the measured phase o from time-of-flight pixel array 410A can be determined as follows:

$$φ = \frac{1}{2} \cdot {tan}^{- 1} ( \frac{{V}_{SF 2 - A 1} - {V}_{SF 1 - A 1} + {V}_{SF 1 - B 1} - {V}_{SF 2 - B 1}}{{V}_{SF 1 - A 2} - {V}_{SF 2 - A 2} + {V}_{SF 2 - B 2} - {V}_{SF 1 - B 2}} ) \qquad ( 11 )$$

Substituting Equations (7), (3), (4), and (8) into the numerator of the arctangent function in Equation (11) results in the following numerator for the arctangent function of Equation (11):

$$( {o}_{A 1} + {CG}_{A 1} \cdot ( {Q}_{180} + D {C}_{1} ) ) - ( {o}_{A 1} + {CG}_{A 1} \cdot ( {Q}_{0} + D {C}_{1} ) ) + ( {o}_{B 1} + {CG}_{B 1} \cdot ( {Q}_{180} + D {C}_{1} ) ) - ( {o}_{B 1} + {CG}_{B 1} \cdot ( {Q}_{0} + D {C}_{1} ) ) \qquad ( 12 )$$

Similarly, substituting Equations (5), (9), (10), and (6) into the denominator of the arctangent function in Equation (11) results in the following denominator the arctangent function of Equation (11):

$$( {o}_{A 2} + {CG}_{A 2} \cdot ( {Q}_{90} + D {C}_{2} ) ) - ( {o}_{A 2} + {CG}_{A 2} \cdot ( {Q}_{270} + D {C}_{2} ) ) + ( {o}_{B 2} + {CG}_{B 2} \cdot ( {Q}_{90} + D {C}_{2} ) ) - ( {o}_{B 2} + {CG}_{B 2} \cdot ( {Q}_{270} + D {C}_{2} ) ) \qquad ( 13 )$$

Expanding Equation (12) results in the following numerator for the arctangent function of Equation (11):

$${o}_{A 1} + ( {CG}_{A 1} \cdot {Q}_{180} ) + ( {CG}_{A 1} \cdot D {C}_{1} ) - {o}_{A 1} - ( {CG}_{A 1} \cdot {Q}_{0} ) - ( {CG}_{A 1} \cdot D {C}_{1} ) + {o}_{B 1} + ( {CG}_{B 1} \cdot {Q}_{180} ) + ( {CG}_{B 1} \cdot D {C}_{1} ) - {o}_{B 1} - ( {CG}_{B 1} \cdot {Q}_{0} ) - ( {CG}_{B 1} \cdot D {C}_{1} ) \qquad ( 14 )$$

Similarly, expanding Equation (13) results in the following denominator for the arctangent function of Equation (11):

$${o}_{A 2} + ( {CG}_{A 2} \cdot {Q}_{90} ) + ( {CG}_{A 2} \cdot D {C}_{2} ) - {o}_{A 2} - ( {CG}_{A 2} \cdot {Q}_{270} ) - ( {CG}_{A 2} \cdot D {C}_{2} ) + {o}_{B 2} + ( {CG}_{B 2} \cdot {Q}_{90} ) + ( {CG}_{B 2} \cdot D {C}_{2} ) - {o}_{B 2} - ( {CG}_{B 2} \cdot {Q}_{270} ) - ( {CG}_{B 2} \cdot D {C}_{2} ) \qquad ( 15 )$$

As can be appreciated in numerator and denominator Equations (14) and (15) above, all of the offset error terms o_{A1}−o_{A1}, o_{B1}−o_{B1}, o_{A2}−o_{A2}, and o_{B2}−o_{B2} cancel or eliminate each other. Similarly, all of the dark current error terms (CG_{A1}·DC₁)−(CG_{A1}·DC₁), (CG_{B1}·DC₁)−(CG_{B1}·DC₁), (CG_{A2}·DC₂)−(CG_{A2}·DC₂), and (CG_{B2}·DC₂)−(CG_{B2}·DC₂) cancel or eliminate each other.

After removing the canceled terms shown in Equations (14) and (15), the measured phase φ from time-of-flight pixel array 410A according to Equation (11) is:

$$φ = \frac{1}{2} \cdot {tan}^{- 1} ( \frac{( {CG}_{A 1} \cdot {Q}_{180} ) - ( {CG}_{A 1} \cdot {Q}_{0} ) + ( {CG}_{B 1} \cdot {Q}_{180} ) - ( {CG}_{B 1} \cdot {Q}_{0} )}{( {CG}_{A 2} \cdot {Q}_{90} ) - ( {CG}_{A 2} \cdot {Q}_{270} ) + ( {CG}_{B 2} \cdot {Q}_{90} ) - ( {CG}_{B 2} \cdot {Q}_{270} )} ) \qquad ( 16 )$$

Simplifying Equation (16) above results in the following Equation (17) to determine measured phase φ from time-of-flight pixel array 410A with the offset errors and dark current errors removed or canceled using only two subframes in accordance with the teachings of the present invention:

$$φ = \frac{1}{2} \cdot {tan}^{- 1} ( \frac{{CG}_{A 1} + {CG}_{B 1}}{{CG}_{A 2} + {CG}_{B 2}} \cdot \frac{{Q}_{180} - {Q}_{0}}{{Q}_{90} - {Q}_{270}} ) \qquad ( 17 )$$

It is appreciated that after the offset errors and dark current errors have been removed or compensated for using the modulation signals with opposing phases in two subframes as discussed above, the remaining term (CG_{A1}+CG_{B1})/(CG_{A2}+CG_{B2}) in the arctangent function of Equation (17) is a remaining conversion gain error. Assuming the relative conversion gain values CG_{A1}, CG_{B1}, CG_{A2}, and CG_{B2} are acceptable, the remaining conversion gain error (CG_{A1}+CG_{B1})/(CG_{A2}+CG_{B2}) in Equation (17) is acceptable.

FIG. 4B is a schematic illustrating another example of time-of-flight pixel circuits 412-1, 412-2, 412-3, 412-4 included in a time-of-flight pixel array 410B of a time-of-flight sensing system in accordance with the teachings of the present invention. It is appreciated that the example of time-of-flight pixel circuits 412-1, 412-2, 412-3, 412-4 illustrated in FIG. 4B may also be examples of the time-of-flight pixel circuit 312 shown in FIG. 3 or the time-of-flight pixel circuits 112 shown in FIG. 1, and/or that example time-of-flight pixel array 410B illustrated in FIG. 4B may be an example of time-of-flight pixel array 110 shown in FIG. 1, and that similarly named and numbered elements described above are coupled and function similarly below. It also appreciated that the example of time-of-flight pixel circuits 412-1, 412-2, 412-3, 412-4 included in a time-of-flight pixel array 410B of FIG. 4A are also substantially similar to the example of time-of-flight pixel circuits 412-1, 412-2, 412-3, 412-4 included in a time-of-flight pixel array 410A of FIG. 4A as well as the time-of-flight pixel circuit 312 shown in FIG. 3.

For instance, each of the example time-of-flight pixel circuits 412-1, 412-2, 412-3, 412-4 depicted in FIG. 4B also includes a photodiode 418 coupled to first and second transfer transistors 420A and 420B. First and second floating diffusions FDA 422A and FDB 422B are coupled to the first and second transfer transistors 420A and 420B, and first and second reset transistors 424A and 424B are coupled to the respective first and second floating diffusions FDA 422A and FDB 422B. First and second sample and hold transistors 426A and 426B are coupled between the respective first and second floating diffusions FDA 422A and FDB 422B and respective first and second memory nodes 434A and 434B, which are coupled to respective first and second capacitors 428A and 428B. First and second source follower transistors 430A and 430B are coupled to respective first and second memory nodes 434A and 434B, and first and second row select transistors 432A and 432B are coupled between the respective first and second source follower transistors 430A and 430B and respective first and second bitlines, which may also be referred to as first and second output taps of each respective time-of-flight pixel circuit 412-1, 412-2, 412-3, 412-4 from which the outputs (e.g. VA1, VB1, VA2, VB2) may be read out.

In the depicted example, the time-of-flight pixel circuits 412-1, 412-2, 412-3, 412-4 are also arranged in rows and columns in the time-of-flight pixel array 410B. For instance, time-of-flight pixel circuits 412-1 and 412-2 are in the same column and time-of-flight pixel circuits 412-3 and 412-4 are in a neighboring column. Stated in another way, time-of-flight pixel circuits 412-1 and 412-3 are in the same row and time-of-flight pixel circuits 412-2 and 412-4 are in a neighboring row.

It is appreciated that operation of the time-of-flight pixel circuits 412-1, 412-2, 412-3, 412-4 of example time-of-flight pixel array 410B of FIG. 4B is nearly identical with the operation of the time-of-flight pixel circuits 412-1, 412-2, 412-3, 412-1 of example time-of-flight pixel array 410A of FIG. 4A. However, a difference between the operation of example time-of-flight pixel array 410B of FIG. 4B is that instead of the time-of-flight pixel circuits 412-1 and 412-3 being modulated with the 0°/180° and 180°/0° phase modulation signals, and the time-of-flight pixel circuits 412-2 and 412-4 being modulated with 90°/270° and 270°/90° phase modulation signals in two subframes based on alternating rows of time-of-flight pixel array 410A as shown in FIG. 4A, the time-of-flight pixel circuits 412-1 and 412-4 are modulated with the 0°/180° and 180°/0° phase modulation signals, and the time-of-flight pixel circuits 412-2 and 412-3 being modulated with 90°/270° and 270°/90° phase modulation signals in two subframes based a checkerboard pattern or mosaic pattern of time-of-flight pixel circuits in time-of-flight pixel array 410B as shown in FIG. 4B. In other words, the time-of-flight pixel circuits that are modulated with the 90°/270° and 270°/90° phase modulation signals (e.g., 412-2, 412-3) are arranged in adjacent neighboring rows and/or in adjacent neighboring columns of the time-of-flight pixel circuits that are modulated with the 0°/180° and 180°/0° phase modulation signals (e.g., 412-1, 412-4) in the checkerboard pattern example shown in time-of-flight pixel array 410B of FIG. 4B. Thus, the time-of-flight pixel circuits that are modulated with the 0°/180° and 180°/0° phase modulation signals (e.g., 412-1, 412-4) and the time-of-flight pixel circuits that are modulated with the 90°/270° and 270°/90° phase modulation signals (e.g., 412-2, 412-3) are included in a checkerboard pattern arrangement of a time-of-flight pixel circuits (e.g., 412-1, 412-2, 412-3, 412-4) included in the time-of-flight pixel array 410B as shown in FIG. 4B.

In the example, operation of the time-of-flight pixel circuits 412-1, 412-2, 412-3, 412-4 of example time-of-flight pixel array 410B of FIG. 4B is otherwise the same as operation of the time-of-flight pixel circuits 412-1, 412-2, 412-3, 412-4 of example time-of-flight pixel array 410A of FIG. 4A. As such, the determination of the measured phase φ from time-of-flight pixel array 410B with the offset errors and dark current errors removed or canceled using only two subframes is the same as the determination of the measured phase φ from time-of-flight pixel array 410A according to Equations (3)-(17) as discussed above in detail in accordance with the teachings of the present invention.

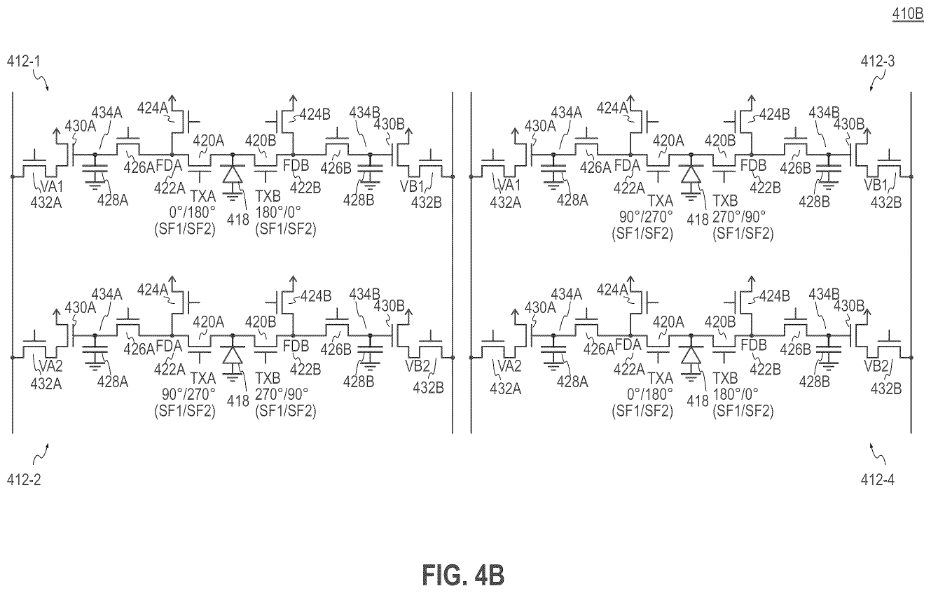

FIG. 5 is a schematic illustrating yet another example of time-of-flight pixel circuits 512-1, 512-2 included in a time-of-flight pixel array 510 of a time-of-flight sensing system in accordance with the teachings of the present invention. It is appreciated that the example of time-of-flight pixel circuits 512-1, 512-2 illustrated in FIG. 5 share many similarities with the time-of-flight pixel circuit 312 shown in FIG. 3, and/or may be examples of the time-of-flight pixel circuits 112 shown in FIG. 1, and/or that example time-of-flight pixel array 510 illustrated in FIG. 5 may be an example of time-of-flight pixel array 110 shown in FIG. 1, and that similarly named and numbered elements described above are coupled and function similarly below.

It is appreciated that one of the differences between the example of time-of-flight pixel circuits 512-1, 512-2 illustrated in FIG. 5 and the example time-of-flight pixel circuit 312 shown in FIG. 3 is that FIG. 5 illustrates an example pixel array 510 including a plurality of pixel circuits 512-1, 512-2 that have a single output tap per time-of-flight pixel circuit 512-1, 512-2 instead of two output taps per time-of-flight pixel circuit 312 as shown in FIG. 3. For instance, the output VA1 may be read out from the 1-tap of pixel circuit 512-1, and the output VA2 may be read out from the 1-tap of pixel circuit 512-2. As such, each of the example time-of-flight pixel circuits 512-1, 512-2 illustrated in FIG. 5 is simplified and does not include a corresponding second floating diffusion FDB 322B, second reset transistor 324B, second sample and hold transistor 326B, second memory node 334, second capacitor 328B, second source follower transistor 330B, or second row select transistor 332B compared to the example time-of-flight pixel circuit 312 depicted in FIG. 3.

Therefore, as illustrated in the example depicted in FIG. 5, each of the example time-of-flight pixel circuits 512-1, 512-2 of pixel array 510 includes a photodiode 518 coupled to first and second transfer transistors 520A and 520B. A first floating diffusions FDA 522A is coupled to the first transfer transistor 520A, and a first reset transistor 524A is coupled to the first floating diffusion FDA 522A. A first sample and hold transistor 526A is coupled between the first floating diffusion FDA 522A and the first memory nodes 534A, which is coupled to first capacitor 528A. A first source follower transistor 530A is coupled to first memory node 534A, and a first row select transistor 532A is coupled between the first source follower transistor 530A and first bitline, which may also be referred to as the first or single output tap of each respective time-of-flight pixel circuit 512-1, 512-2.

In the depicted example, it is appreciated that time-of-flight pixel circuit 512-1 and neighboring pixel circuit 512-2 are arranged in neighboring rows of the time-of-flight pixel array 510. In another example, it is appreciated that time-of-flight pixel circuit 512-1 and neighboring time-of-flight pixel circuit 512-2 may be arranged in neighboring columns of the time-of-flight pixel array 510.

In operation, each of plurality of photodiodes 518 of the time-of-flight pixel circuits 512-1, 512-2 is configured to generate charge in response to reflected modulated light (e.g., reflected light 108) incident upon the plurality of photodiodes 518. In the example, the photodiode 518 of time-of-flight pixel circuit 512-1 may be considered to be a first photodiode 518 of time-of-flight pixel array 510. In the example, the transfer transistor 520A of time-of-flight pixel circuit 512-1 may be considered to be a first transfer transistor 520A and the transfer transistor 520B of time-of-flight pixel circuit 512-1 may be considered to be a second transfer transistor 520B of time-of-flight pixel array 510.

In operation, the first transfer transistor 520A of time-of-flight pixel circuit 512-1 is configured to transfer a first phase portion of the charge (e.g., Q1) from the first photodiode 518 of time-of-flight pixel circuit 512-1 in response to a first phase modulation signal (e.g., 0° phase modulation signal 214A) during a first subframe (e.g., SF1). In the example, the first transfer transistor 520A of time-of-flight pixel circuit 512-1 is configured to transfer a second phase portion of the charge (e.g., Q2) from the first photodiode 518 of time-of-flight pixel circuit 512-1 in response to a second phase modulation signal (e.g., 180° phase modulation signal 214B) during a second subframe (e.g., SF2).

Continuing with the example, the second transfer transistor 520B of time-of-flight pixel circuit 512-1 is configured to transfer the second phase portion of the charge (e.g., Q2) from the first photodiode 518 of time-of-flight pixel circuit 512-1 in response to the second phase modulation signal (e.g., 180° phase modulation signal 214B) during the first subframe (e.g., SF1). In the example, the second transfer transistor 520B of time-of-flight pixel circuit 512-1 is configured to transfer the first phase portion of the charge (e.g., Q1) from the first photodiode 518 of time-of-flight pixel circuit 512-1 in response to the first phase modulation signal (e.g., 0° phase modulation signal 214A) during the second subframe (e.g., SF2).

In the depicted example, the photodiode 518 of time-of-flight pixel circuit 512-2 in the neighboring row may be considered to be a second photodiode 518 of time-of-flight pixel array 510A. Similarly, the transfer transistor 520A of time-of-flight pixel circuit 512-2 may be considered to be a third transfer transistor 520A and the transfer transistor 520B of time-of-flight pixel circuit 512-2 may be considered to be a fourth transfer transistor 520B of time-of-flight pixel array 510A.

In operation, the third transfer transistor 520A of time-of-flight pixel circuit 512-2 is configured to transfer a third phase portion of the charge (e.g., Q3) from the second photodiode 518 of time-of-flight pixel circuit 512-2 in response to a third phase modulation signal (e.g., 90° phase modulation signal 216A) during the first subframe (e.g., SF1). In the example, the third transfer transistor 520A of time-of-flight pixel circuit 512-2 is configured to transfer a fourth phase portion of the charge (e.g., Q4) from the second photodiode 518 of time-of-flight pixel circuit 512-2 in response to a fourth phase modulation signal (e.g., 270° phase modulation signal 216B) during the second subframe (e.g., SF2).

Continuing with the example, the fourth transfer transistor 520B of time-of-flight pixel circuit 512-2 is configured to transfer the fourth phase portion of the charge (e.g., Q4) from the second photodiode 518 of time-of-flight pixel circuit 512-2 in response to the fourth phase modulation signal (e.g., 270° phase modulation signal 216B) during the first subframe (e.g., SF1). In the example, the fourth transfer transistor 520B of time-of-flight pixel circuit 512-2 is configured to transfer the third phase portion of the charge (e.g., Q3) from the second photodiode 518 of time-of-flight pixel circuit 512-2 in response to the third phase modulation signal (e.g., 90° phase modulation signal 216A) during the second subframe (e.g., SF2).

Therefore, it is appreciated that the time-of-flight pixel circuit 512-1 is modulated with 0°/180° phase modulation signals 214A and 214B in a first subframe (e.g., SF1) and then with opposing 180°/0° phase modulation signals 214B and 214A in a second subframe (e.g. SF2). Similarly, it is appreciated that the neighboring time-of-flight pixel circuit 512-2 in the neighboring row is modulated with 90°/270° phase modulations signals 216A and 216B in the first subframe (e.g., SF1) and then with opposing 270°/90° phase modulation signals 216B and 216A in the second subframe (e.g., SF2).

Similar to the examples depicted in FIG. 4A and FIG. 4B, by modulating the time-of-flight pixel circuits 512-1, 512-2 with the opposing phases of the 0°/180° and 180°/0° phase modulations signals as well as with the opposing phases of the 90°/270° and 270°/90° phase modulation signals in the two subframes as described, offset errors as well as dark current errors in the time-of-flight pixel circuits 512-1, 512-2 in time-of-flight pixel array 510 are also canceled or removed in accordance with the teachings of the present invention.

Similar the examples discussed above in FIG. 4A and FIG. 4B, the following relationships regarding the time-of-flight pixel circuits 512-1, 512-2 of time-of-flight pixel array 510 are given:

$${V}_{SF 1 - A 1} = {V}_{A 1} = {o}_{A 1} + {CG}_{A 1} \cdot ( {Q}_{0} + D {C}_{1} ) \qquad ( 18 )$$

In Equation (18), V_{SF1-A1} represents the voltage V_{A1} at the output tap of time-of-flight pixel circuit 512-1 during the first subframe SF1, o_{A1} represents the offset error at the output tap of time-of-flight pixel circuit 512-1, CG_{A1} represents the conversion gain at the output tap of time-of-flight pixel circuit 512-1, Q₀ represents the 0° phase portion of charge (e.g., Q1), and DC₁ represents the dark current error of time-of-flight pixel circuit 512-1.

$${V}_{SF 1 - A 2} = {V}_{A 2} = {o}_{A 2} + {CG}_{A 2} \cdot ( {Q}_{90} + D {C}_{2} ) \qquad ( 19 )$$

In Equation (19), V_{SF1-A2} represents the voltage V_{A2} at the output tap of time-of-flight pixel circuit 512-2 during the first subframe SF1, o_{A2} represents the offset error at the output tap of time-of-flight pixel circuit 512-2, CG_{A2} represents the conversion gain at the output tap of time-of-flight pixel circuit 512-2, Q₉₀ represents the 90° phase portion of charge (e.g., Q3), and DC₂ represents the dark current error of time-of-flight pixel circuit 512-2.

$${V}_{SF 2 - A 1} = {V}_{A 1} = {o}_{A 1} + {CG}_{A 1} \cdot ( {Q}_{180} + D {C}_{1} ) \qquad ( 20 )$$

In Equation (20), V_{SF2-A1} represents the voltage V_{A1} at the output tap of time-of-flight pixel circuit 512-1 during the second subframe SF2, o_{A1} represents the offset error at the output tap of time-of-flight pixel circuit 512-1, CG_{A1} represents the conversion gain at the output tap of time-of-flight pixel circuit 512-1, Q₁₈₀ represents the 180° phase portion of charge (e.g., Q3), and DC₁ represents the dark current error of time-of-flight pixel circuit 512-1.

$${V}_{SF 2 - A 2} = {V}_{A 2} = {o}_{A 2} + {CG}_{A 2} \cdot ( {Q}_{270} + D {C}_{2} ) \qquad ( 21 )$$

In Equation (21), V_{SF2-A2} represents the voltage V_{A2} at the output tap of time-of-flight pixel circuit 512-2 during the second subframe SF2, o_{A2} represents the offset error at the output tap of time-of-flight pixel circuit 512-2, CG_{A2} represents the conversion gain at the output tap of time-of-flight pixel circuit 512-2, Q₂₇₀ represents the 270° phase portion of charge (e.g., Q4), and DC₂ represents the dark current error of time-of-flight pixel circuit 512-2.

With the relationships given in Equations (18)-(21), the measured phase φ from time-of-flight pixel array 510 can be determined as follows:

$$φ = \frac{1}{2} \cdot {tan}^{- 1} ( \frac{{V}_{SF 2 - A 1} - {V}_{SF 1 - A 1}}{{V}_{SF 1 - A 2} - {V}_{SF 2 - A 2}} ) \qquad ( 22 )$$

Substituting Equations (21), (18), (19), and (21) into Equation (22) results in the following equation to determine the measured phase φ from time-of-flight pixel array 510:

$$φ = \frac{1}{2} \cdot {tan}^{- 1} ( \frac{( {o}_{A 1} + {CG}_{A 1} \cdot ( {Q}_{180} + D {C}_{1} ) ) - ( {o}_{A 1} + {CG}_{A 1} \cdot ( {Q}_{0} + D {C}_{1} ) )}{( {o}_{A 2} + {CG}_{A 2} \cdot ( {Q}_{90} + D {C}_{2} ) ) - ( {o}_{A 2} + {CG}_{A 2} \cdot ( {Q}_{270} + D {C}_{2} ) )} ) \qquad ( 23 )$$

Expanding Equation (23) above results in:

$$φ = \frac{1}{2} \cdot {tan}^{- 1} ( \frac{{o}_{A 1} + ( {CG}_{A 1} \cdot {Q}_{180} ) + ( {CG}_{A 1} \cdot D {C}_{1} ) - {o}_{A 1} - ( {CG}_{A 1} \cdot {Q}_{0} ) - ( {CG}_{A 1} \cdot D {C}_{1} )}{{o}_{A 2} + ( {CG}_{A 2} \cdot {Q}_{90} ) + ( {CG}_{A 2} \cdot D {C}_{2} ) - {o}_{A 2} - ( {CG}_{A 2} \cdot {Q}_{270} ) - ( {CG}_{A 2} \cdot D {C}_{2} ) )} ) \qquad ( 24 )$$

As can be appreciated in Equation (24) above, all of the offset error terms o_{A1}−o_{A1}, and o_{A2}−o_{A2} cancel or eliminate each other. Similarly, all of the dark current error terms (CG_{A1}·DC₁)−(CG_{A1}·DC₁) and (CG_{A2}·DC₂)−(CG_{A2}·DC₂) cancel or eliminate each other.

After removing the canceled terms shown in Equations (24), the measured phase φ from time-of-flight pixel array 510 according to Equation (22) is:

$$φ = \frac{1}{2} \cdot {tan}^{- 1} ( \frac{( {CG}_{A 1} \cdot {Q}_{180} ) - ( {CG}_{A 1} \cdot {Q}_{0} )}{( {CG}_{A 2} \cdot {Q}_{90} ) - ( {CG}_{A 2} \cdot {Q}_{270} )} ) \qquad ( 25 )$$

Simplifying Equation (25) above results in the following Equation (26) to determine measured phase φ from time-of-flight pixel array 510 with the offset errors and dark current errors removed or canceled using only two subframes in accordance with the teachings of the present invention:

$$φ = \frac{1}{2} \cdot {tan}^{- 1} ( \frac{{CG}_{A 1}}{{CG}_{A 2}} \cdot \frac{{Q}_{180} - {Q}_{0}}{{Q}_{90} - {Q}_{270}} ) \qquad ( 26 )$$

It is appreciated that after the offset errors and dark current errors have been removed or compensated for using the modulation signals with opposing phases in two subframes as discussed above, the remaining term (CG_{A1})/(CG_{A2}) in the arctangent function of Equation (26) is a remaining conversion gain error. Assuming the relative conversion gain values CG_{A1} and CG_{A2} are acceptable, the remaining conversion gain error (CG_{A1})/(CG_{A2}) in Equation (26) is acceptable.

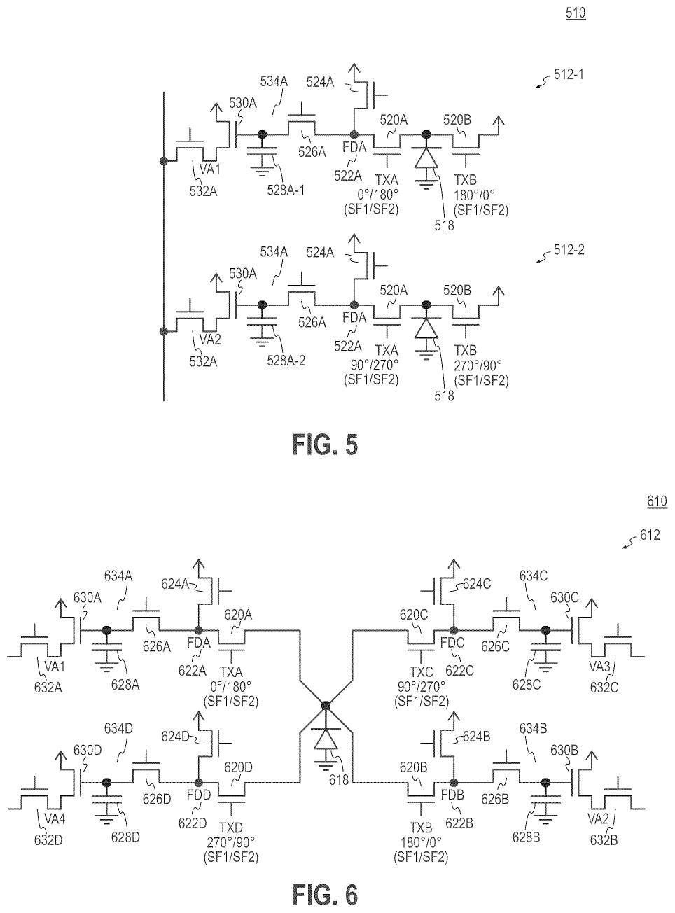

FIG. 6 is a schematic illustrating still another example of a time-of-flight pixel circuit 612 included in a time-of-flight pixel array 610 of a time-of-flight sensing system in accordance with the teachings of the present invention. It is appreciated that the example of time-of-flight pixel circuit 612 illustrated in FIG. 6 share many similarities with the time-of-flight pixel circuit 312 shown in FIG. 3, and/or may be an example of the time-of-flight pixel circuits 112 shown in FIG. 1, and/or that example time-of-flight pixel array 610 illustrated in FIG. 6 may be an example of time-of-flight pixel array 110 shown in FIG. 1, and that similarly named and numbered elements described above are coupled and function similarly below.

It is appreciated that one of the differences between the example of time-of-flight pixel circuit 612 illustrated in FIG. 6 and the example time-of-flight pixel circuit 312 shown in FIG. 3 is that FIG. 6 illustrates a time-of-flight pixel circuit 612 that has four output taps per pixel circuit 612 instead of two output taps per time-of-flight pixel circuit 312 as shown in FIG. 3. As such, each of the time-of-flight pixel circuits 612 included in a time-of-flight pixel array 610 as illustrated in FIG. 6 is coupled to receive a 0° phase modulation signal 214A (e.g., a first phase modulation signal), a 180° phase modulation signal 214B (e.g., a second phase modulation signal), a 90° phase modulation signal 216A (e.g., a third phase modulation signal), and a 270° phase modulation signal 216B (e.g., a fourth phase modulation signal).

As a result, another difference between the example of time-of-flight pixel circuit 612 illustrated in FIG. 6 and the example time-of-flight pixel circuit 312 shown in FIG. 3 is that FIG. 6 illustrates a time-of-flight pixel circuit 612 in which the photodiode 618 is coupled to four transfer transistors instead of two transfer transistors as shown in time-of-flight pixel circuit 312 of FIG. 3.

In particular, the example depicted in FIG. 6 shows photodiode 618 coupled to first, second, third, and fourth transfer transistors 620A, 620B, 620C, and 620B. First, second, third, and fourth floating diffusions FDA 622A, FDB 622B, FDC 622C, and FDD 622D are coupled to the first, second, third, and fourth transfer transistors 620A, 620B, 620C, and 620D. First, second, third, and fourth reset transistors 624A, 624B, 624C, and 624d are coupled to the respective first, second, third, and fourth floating diffusions FDA 422A and FDB 422B. First and second sample and hold transistors 426A and 426B are coupled between the respective first and second floating diffusions FDA 622A, FDB 622B, FDC 622C, and FDD 622D and respective first, second, third, and fourth memory nodes 634A, 634B, 634C, and 634D, which are coupled to respective first, second, third, and fourth capacitors 628A, 628B, 628C, and 628D. First, second, third, and fourth source follower transistors 630A, 630B, 630C, and 630D are coupled to respective first, second, third, and fourth memory nodes 634A, 634B, 634C, and 634D. First, second, third, and fourth row select transistors 632A, 632B, 632C, and 632D are coupled to the respective first, second, third, and fourth source follower transistors 630A, 630B, 630C, and 630D to provide respective outputs of pixel circuit 612, which may also be referred to as first, second, third, and fourth output taps of time-of-flight pixel circuit 612.

For instance, the VA1 output may be read out from the first output tap through row select transistor 632A, the VA2 output may be read out from the second output tap through row select transistor 632B, the VA3 output may be read out from the third output tap through row select transistor 632C, and the VA4 output may be read out from the fourth output tap through row select transistor 632D.

In operation, the photodiode 618 of time-of-flight pixel circuit 612 is configured to generate charge in response to reflected modulated light (e.g., reflected light 108) incident upon photodiode 618. In the example, the transfer transistor 620A may be considered to be a first transfer transistor 620A, the transfer transistor 620B may be considered to be a second transfer transistor 620B, the transfer transistor 620C may be considered to be a third transfer transistor 620C, and the transfer transistor 620D may be considered to be a fourth transfer transistor 620D.

In operation, the first transfer transistor 620A is configured to transfer a first phase portion of the charge (e.g., Q1) from the photodiode 618 in response to a first phase modulation signal (e.g., 0° phase modulation signal 214A) during a first subframe (e.g., SF1). In the example, the first transfer transistor 620A is configured to transfer a second phase portion of the charge (e.g., Q2) from the photodiode 618 in response to a second phase modulation signal (e.g., 180° phase modulation signal 214B) during a second subframe (e.g., SF2).

Continuing with the example, the second transfer transistor 620B is configured to transfer the second phase portion of the charge (e.g., Q2) from the photodiode 618 of pixel circuit 612-1 in response to the second phase modulation signal (e.g., 180° phase modulation signal 214B) during the first subframe (e.g., SF1). In the example, the second transfer transistor 620B is configured to transfer the first phase portion of the charge (e.g., Q1) from the photodiode 618 in response to the first phase modulation signal (e.g., 0° phase modulation signal 214A) during the second subframe (e.g., SF2).

In the example, the third transfer transistor 620C is configured to transfer a third phase portion of the charge (e.g., Q3) from the photodiode 618 in response to a third phase modulation signal (e.g., 90° phase modulation signal 216A) during the first subframe (e.g., SF1). In the example, the third transfer transistor 620C is configured to transfer a fourth phase portion of the charge (e.g., Q4) from the photodiode 618 in response to a fourth phase modulation signal (e.g., 270° phase modulation signal 216B) during the second subframe (e.g., SF2).

Continuing with the example, the fourth transfer transistor 620D is configured to transfer the fourth phase portion of the charge (e.g., Q4) from the photodiode 618 in response to the fourth phase modulation signal (e.g., 270° phase modulation signal 216B) during the first subframe (e.g., SF1). In the example, the fourth transfer transistor 620D is configured to transfer the third phase portion of the charge (e.g., Q3) from the photodiode 618 in response to the third phase modulation signal (e.g., 90° phase modulation signal 216A) during the second subframe (e.g., SF2).

Therefore, it is appreciated that the first, third, second, and fourth transfer transistors 620A, 620C, 620B, and 620D of pixel circuit 612 are modulated with 0°, 90°, 180°, and 270° phase modulation signals 214A, 216A, 214B, and 216B in a first subframe (e.g., SF1), and then with opposing 180°, 270°, 0°, and 90° phase modulation signals 214B, 216B, 214A, and 216A in a second subframe (e.g. SF2). By modulating the first, third, second, and fourth transfer transistors 620A, 620C, 620B, and 620D of pixel circuit 612 with the opposing phases of the 0°/180°, 90°/270°, 180°/0°, and 270°/90° phase modulations signals in the two subframes as described, offset errors as well as dark current errors in the time-of-flight pixel circuits are canceled or removed in accordance with the teachings of the present invention.

In one example, it is noted that each of the first, third, second, and fourth transfer transistors 620A, 620C, 620B, and 620D is arranged around photodiode 618 in the semiconductor substrate of pixel circuit 612 as shown to have minimal distance between the output taps associated with subsequent transfer phases (e.g., 0°/90°/180°/270°), which yields improved charge transfer performance. In so doing, the phase assignments are arranged such as to apply close phases (e.g., 0°-90°, 90°-180°, 180°-270°, 270°-360°) to close modulation transfer transistors in the semiconductor substrate such as to minimize carrier travel times at the distribution node of the photodiode 618. As such, the disclosed offset compensation scheme preserves optimal charge transfer in accordance with teachings of the present invention.

The above description of illustrated examples of the invention, including what is described in the Abstract, is not intended to be exhaustive or to limit the invention to the precise forms disclosed. While specific examples of the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific examples disclosed in the specification. Rather, the scope of the invention is to be determined entirely by the following claims, which are to be construed in accordance with established doctrines of claim interpretation.

What is claimed is:

1. A time-of-flight pixel array, comprising:
a plurality of photodiodes configured to generate charge in response to reflected modulated light incident upon the plurality of photodiodes; and
a plurality of transfer transistors coupled to the plurality of photodiodes, wherein the plurality of transfer transistors includes a plurality of first transfer transistors, a plurality of second transfer transistors, a plurality of third transfer transistors, and a plurality of fourth transfer transistors,
wherein the plurality of first transfer transistors is configured to transfer a first phase portion of the charge from the plurality of photodiodes in response to a first phase modulation signal during a first subframe, wherein the plurality of first transfer transistors is configured to transfer a second phase portion of the charge from the plurality of photodiodes in response to a second phase modulation signal during a second subframe, wherein the second phase modulation signal is an inverted first phase modulation signal,
wherein the plurality of second transfer transistors is configured to transfer the second phase portion of the charge from the plurality of photodiodes in response to the second phase modulation signal during the first subframe, wherein the plurality of second transfer transistors is configured to transfer the first phase portion of the charge from the plurality of photodiodes in response to the first phase modulation signal during the second subframe,
wherein the plurality of third transfer transistors is configured to transfer a third phase portion of the charge from the plurality of photodiodes in response to a third phase modulation signal during the first subframe, wherein the third phase modulation signal is ninety degrees out of phase with the first phase modulation signal, wherein the plurality of third transfer transistors is configured to transfer a fourth phase portion of the charge from the plurality of photodiodes in response to a fourth phase modulation signal during the second subframe, wherein the fourth phase modulation signal is an inverted third phase modulation signal,
wherein the plurality of fourth transfer transistors is configured to transfer the fourth phase portion of the charge from the plurality of photodiodes in response to the fourth phase modulation signal during the first subframe, wherein the plurality of fourth transfer transistors is configured to transfer the third phase portion of the charge from the plurality of photodiodes in response to the third phase modulation signal during the second subframe.

2. The time-of-flight pixel array of claim 1, wherein a time-of-flight of the reflected modulated light from an object to the time-of-flight pixel array is determined in response to an arctangent of a quotient of a difference between the first phase portion and the second phase portion of the charge transferred through the plurality of first transfer transistors and through the plurality of second transfer transistors, and a difference between the third phase portion and the fourth phase portion of the charge transferred through the plurality of third transfer transistors and through the plurality of fourth transfer transistors.

3. The time-of-flight pixel array of claim 1, wherein a time-of-flight of the reflected modulated light from an object to the time-of-flight pixel array is determined in response to an arctangent of a quotient of a difference between the first phase portion and the second phase portion of the charge transferred through the plurality of first transfer transistors, and a difference between the third phase portion and the fourth phase portion of the charge transferred through the plurality of third transfer transistors.

4. The time-of-flight pixel array of claim 1, further comprising a plurality of pixel circuits, wherein the plurality of pixel circuits comprises:
a first pixel circuit, comprising:
a first one of the plurality of photodiodes;
a first one of the plurality of first transfer transistors coupled to the first one of the plurality of photodiodes; and
a first one of the plurality of second transfer transistors coupled to the first one of the plurality of photodiodes; and
a second pixel circuit neighboring the first pixel circuit in the time-of flight pixel array, wherein the second pixel circuit comprises:
a second one of the plurality of photodiodes;
a first one of the plurality of third transfer transistors coupled to the second one of the plurality of photodiodes; and
a first one of the plurality of fourth transfer transistors coupled to the second one of the plurality of photodiodes.

5. The time-of-flight pixel array of claim 4, wherein the second pixel circuit is in a neighboring row of the time-of-flight pixel array relative to the first pixel circuit.

6. The time-of-flight pixel array of claim 4, wherein the second pixel circuit is in a neighboring column or a neighboring row of the time-of-flight pixel array relative to the first pixel circuit.

7. The time-of-flight pixel array of claim 6, wherein the first pixel circuit and the second pixel circuit are included in a checkerboard pattern arrangement of a plurality of first pixel circuits and a plurality of second pixel circuits included in the plurality of pixel circuits of the time-of-flight pixel array.

8. The time-of-flight pixel array of claim 4,
wherein the first pixel circuit further comprises a first floating diffusion coupled to the first one of the plurality of first transfer transistors to receive the first phase portion of the charge during the first subframe and the second phase portion of the charge during the second subframe,
wherein the second pixel circuit further comprises a third floating diffusion coupled to the first one of the plurality of third transfer transistors to receive the third phase portion of the charge during the first subframe and the fourth phase portion of the charge during the second subframe.

9. The time-of-flight pixel array of claim 8,
wherein the first pixel circuit further comprises a first reset transistor coupled between a supply rail and the first floating diffusion, wherein the first reset transistor is configured to reset the first floating diffusion,
wherein the second pixel circuit further comprises a third reset transistor coupled between the supply rail and the third floating diffusion, wherein the third reset transistor is configured to reset the third floating diffusion.

10. The time-of-flight pixel array of claim 9,
wherein the first pixel circuit further comprises a first sample and hold transistor coupled between a first storage node and the first floating diffusion, wherein the first storage node is configured to store the first phase portion of the charge during the first subframe and the second phase portion of the charge during the second subframe from the first floating diffusion through the first sample and hold transistor,
wherein the second pixel circuit further comprises a third sample and hold transistor coupled between a third storage node and the third floating diffusion, wherein the third storage node is configured to store the third phase portion of the charge during the first subframe and the fourth phase portion of the charge during the second subframe from the third floating diffusion through the third sample and hold transistor.

11. The time-of-flight pixel array of claim 10,
wherein the first pixel circuit further comprises:
a first source follower transistor having a gate coupled to the first storage node; and
a first row select transistor coupled to a source of the first source follower transistor,
wherein the second pixel circuit further comprises:
a third source follower transistor having a gate coupled to the third storage node; and
a third row select transistor coupled to a source of the third source follower transistor.

12. The time-of-flight pixel array of claim 11,
wherein the first pixel circuit further comprises a second floating diffusion coupled to the first one of the plurality of second transfer transistors to receive the second phase portion of the charge during the first subframe and the first phase portion of the charge during the second subframe,
wherein the second pixel circuit further comprises a fourth floating diffusion coupled to the first one of the plurality of fourth transfer transistors to receive the fourth phase portion of the charge during the first subframe and the third phase portion of the charge during the second subframe.

13. The time-of-flight pixel array of claim 12,
wherein the first pixel circuit further comprises a second reset transistor coupled between the supply rail and the second floating diffusion, wherein the second reset transistor is configured to reset the second floating diffusion,
wherein the second pixel circuit further comprises a fourth reset transistor coupled between the supply rail and the fourth floating diffusion, wherein the fourth reset transistor is configured to reset the fourth floating diffusion.

14. The time-of-flight pixel array of claim 13,
wherein the first pixel circuit further comprises a second sample and hold transistor coupled between a second storage node and the second floating diffusion, wherein the second storage node is configured to store the second phase portion of the charge during the first subframe and the first phase portion of the charge during the second subframe from the second floating diffusion through the second sample and hold transistor,
wherein the second pixel circuit further comprises a fourth sample and hold transistor coupled between a fourth storage node and the fourth floating diffusion, wherein the fourth storage node is configured to store the fourth phase portion of the charge during the first subframe and the third phase portion of the charge during the second subframe from the fourth floating diffusion through the fourth sample and hold transistor.

15. The time-of-flight pixel array of claim 14,
wherein the first pixel circuit further comprises:
a second source follower transistor having a gate coupled to the second storage node; and
a second row select transistor coupled to the second source follower transistor,
wherein the second pixel circuit further comprises:
a fourth source follower transistor having a gate coupled to the fourth storage node; and
a fourth row select transistor coupled to the second source follower transistor.

16. The time-of-flight pixel array of claim 1, further comprising a plurality of pixel circuits, wherein each of the plurality of pixel circuits comprises:
one of the plurality of photodiodes;
one of the plurality of first transfer transistors coupled to said one of the plurality of photodiodes;
one of the plurality of second transfer transistors coupled to said one of the plurality of photodiodes;
one of the plurality of third transfer transistors coupled to said one of the plurality of photodiodes; and
one of the plurality of fourth transfer transistors coupled to said one of the plurality of photodiodes.

17. The time-of-flight pixel array of claim 16, wherein each of the plurality of pixel circuits further comprises:
a first floating diffusion coupled to said one of the plurality of first transfer transistors to receive the first phase portion of the charge during the first subframe and the second phase portion of the charge during the second subframe;
a second floating diffusion coupled to said one of the plurality of second transfer transistors to receive the second phase portion of the charge during the first subframe and the first phase portion of the charge during the second subframe;
a third floating diffusion coupled to said one of the plurality of third transfer transistors to receive the third phase portion of the charge during the first subframe and the fourth phase portion of the charge during the second subframe; and
a fourth floating diffusion coupled to said one of the plurality of fourth transfer transistors to receive the fourth phase portion of the charge during the first subframe and the third phase portion of the charge during the second subframe.

18. The time-of-flight pixel array of claim 17, wherein each one of the plurality of pixel circuits further comprises:
a first reset transistor coupled between a supply rail and the first floating diffusion, wherein the first reset transistor is configured to reset the first floating diffusion;
a second reset transistor coupled between the supply rail and the second floating diffusion, wherein the second reset transistor is configured to reset the second floating diffusion;
a third reset transistor coupled between the supply rail and the third floating diffusion, wherein the third reset transistor is configured to reset the third floating diffusion;
a fourth reset transistor coupled between the supply rail and the fourth floating diffusion, wherein the fourth reset transistor is configured to reset the fourth floating diffusion.

19. The time-of-flight pixel array of claim 18, wherein each one of the plurality of pixel circuits further comprises:
a first sample and hold transistor coupled between a first storage node and the first floating diffusion, wherein the first storage node is configured to store the first phase portion of the charge during the first subframe and the second phase portion of the charge during the second subframe from the first floating diffusion through the first sample and hold transistor;
a second sample and hold transistor coupled between a second storage node and the second floating diffusion, wherein the second storage node is configured to store the second phase portion of the charge during the first subframe and the first phase portion of the charge during the second subframe from the second floating diffusion through the second sample and hold transistor;
a third sample and hold transistor coupled between a third storage node and the third floating diffusion, wherein the third storage node is configured to store the third phase portion of the charge during the first subframe and the fourth phase portion of the charge during the second subframe from the third floating diffusion through the third sample and hold transistor; and
a fourth sample and hold transistor coupled between a fourth storage node and the fourth floating diffusion, wherein the fourth storage node is configured to store the fourth phase portion of the charge during the first subframe and the third phase portion of the charge during the second subframe from the fourth floating diffusion through the fourth sample and hold transistor.

20. The time-of-flight pixel array of claim 19, wherein each one of the plurality of pixel circuits further comprises:
a first source follower transistor having a gate coupled to the first storage node;
a first row select transistor coupled to a source of the first source follower transistor;
a second source follower transistor having a gate coupled to the second storage node;
a second row select transistor coupled to the second source follower transistor;
a third source follower transistor having a gate coupled to the third storage node;
a third row select transistor coupled to a source of the third source follower transistor;
a fourth source follower transistor having a gate coupled to the fourth storage node; and
a fourth row select transistor coupled to the second source follower transistor.

21. A time-of-flight sensing system, comprising:
a light source configured to emit modulated light to an object; and
a time-of-flight pixel array configured to be illuminated with reflected modulated light from the object, wherein the time-of-flight pixel array comprises:
a plurality of photodiodes configured to generate charge in response to the reflected modulated light incident upon the plurality of photodiodes; and
a plurality of transfer transistors coupled to the plurality of photodiodes, wherein the plurality of transfer transistors includes a plurality of first transfer transistors, a plurality of second transfer transistors, a plurality of third transfer transistors, and a plurality of fourth transfer transistors,
wherein the plurality of first transfer transistors is configured to transfer a first phase portion of the charge from the plurality of photodiodes in response to a first phase modulation signal during a first subframe, wherein the plurality of first transfer transistors is configured to transfer a second phase portion of the charge from the plurality of photodiodes in response to a second phase modulation signal during a second subframe, wherein the second phase modulation signal is an inverted first phase modulation signal,
wherein the plurality of second transfer transistors is configured to transfer the second phase portion of the charge from the plurality of photodiodes in response to the second phase modulation signal during the first subframe, wherein the plurality of second transfer transistors is configured to transfer the first phase portion of the charge from the plurality of photodiodes in response to the first phase modulation signal during the second subframe,
wherein the plurality of third transfer transistors is configured to transfer a third phase portion of the charge from the plurality of photodiodes in response to a third phase modulation signal during the first subframe, wherein the third phase modulation signal is ninety degrees out of phase with the first phase modulation signal, wherein the plurality of third transfer transistors is configured to transfer a fourth phase portion of the charge from the plurality of photodiodes in response to a fourth phase modulation signal during the second subframe, wherein the fourth phase modulation signal is an inverted third phase modulation signal,
wherein the plurality of fourth transfer transistors is configured to transfer the fourth phase portion of the charge from the plurality of photodiodes in response to the fourth phase modulation signal during the first subframe, wherein the plurality of fourth transfer transistors is configured to transfer the third phase portion of the charge from the plurality of photodiodes in response to the third phase modulation signal during the second subframe.

22. The time-of-flight sensing system of claim 21, wherein a time-of-flight of the reflected modulated light from an object to the time-of-flight sensing system is determined in response to an arctangent of a quotient of a difference between the first phase portion and the second phase portion of the charge transferred through the plurality of first transfer transistors and through the plurality of second transfer transistors, and a difference between the third phase portion and the fourth phase portion of the charge transferred through the plurality of third transfer transistors and through the plurality of fourth transfer transistors.

23. The time-of-flight sensing system of claim 21, wherein a time-of-flight of the reflected modulated light from an object to the time-of-flight sensing system is determined in response to an arctangent of a quotient of a difference between the first phase portion and the second phase portion of the charge transferred through the plurality of first transfer transistors, and a difference between the third phase portion and the fourth phase portion of the charge transferred through the plurality of third transfer transistors.

24. The time-of-flight sensing system of claim 21, wherein the time-of-flight pixel array further comprises a plurality of pixel circuits, wherein the plurality of pixel circuits comprises:
a first pixel circuit, comprising:
a first one of the plurality of photodiodes;
a first one of the plurality of first transfer transistors coupled to the first one of the plurality of photodiodes; and
a first one of the plurality of second transfer transistors coupled to the first one of the plurality of photodiodes; and
a second pixel circuit neighboring the first pixel circuit in the time-of flight pixel array, wherein the second pixel circuit comprises:
a second one of the plurality of photodiodes;
a first one of the plurality of third transfer transistors coupled to the second one of the plurality of photodiodes; and
a first one of the plurality of fourth transfer transistors coupled to the second one of the plurality of photodiodes.

25. The time-of-flight sensing system of claim 24, wherein the second pixel circuit is in a neighboring row of the time-of-flight pixel array relative to the first pixel circuit.

26. The time-of-flight sensing system of claim 24, wherein the second pixel circuit is in a neighboring column or a neighboring row of the time-of-flight pixel array relative to the first pixel circuit.

27. The time-of-flight sensing system of claim 26, wherein the first pixel circuit and the second pixel circuit are included in a checkerboard pattern arrangement of a plurality of first pixel circuits and a plurality of second pixel circuits included in the plurality of pixel circuits of the time-of-flight pixel array

28. The time-of-flight sensing system of claim 24,
wherein the first pixel circuit further comprises a first floating diffusion coupled to the first one of the plurality of first transfer transistors to receive the first phase portion of the charge during the first subframe and the second phase portion of the charge during the second subframe,
wherein the second pixel circuit further comprises a third floating diffusion coupled to the first one of the plurality of third transfer transistors to receive the third phase portion of the charge during the first subframe and the fourth phase portion of the charge during the second subframe.

29. The time-of-flight sensing system of claim 28,
wherein the first pixel circuit further comprises a first reset transistor coupled between a supply rail and the first floating diffusion, wherein the first reset transistor is configured to reset the first floating diffusion,
wherein the second pixel circuit further comprises a third reset transistor coupled between the supply rail and the third floating diffusion, wherein the third reset transistor is configured to reset the third floating diffusion.

30. The time-of-flight sensing system of claim 29,
wherein the first pixel circuit further comprises a first sample and hold transistor coupled between a first storage node and the first floating diffusion, wherein the first storage node is configured to store the first phase portion of the charge during the first subframe and the second phase portion of the charge during the second subframe from the first floating diffusion through the first sample and hold transistor,
wherein the second pixel circuit further comprises a third sample and hold transistor coupled between a third storage node and the third floating diffusion, wherein the third storage node is configured to store the third phase portion of the charge during the first subframe and the fourth phase portion of the charge during the second subframe from the third floating diffusion through the third sample and hold transistor.

31. The time-of-flight sensing system of claim 30,
wherein the first pixel circuit further comprises:
a first source follower transistor having a gate coupled to the first storage node; and
a first row select transistor coupled to a source of the first source follower transistor,
wherein the second pixel circuit further comprises:
a third source follower transistor having a gate coupled to the third storage node; and
a third row select transistor coupled to a source of the third source follower transistor.

32. The time-of-flight sensing system of claim 31,
wherein the first pixel circuit further comprises a second floating diffusion coupled to the first one of the plurality of second transfer transistors to receive the second phase portion of the charge during the first subframe and the first phase portion of the charge during the second subframe,
wherein the second pixel circuit further comprises a fourth floating diffusion coupled to the first one of the plurality of fourth transfer transistors to receive the fourth phase portion of the charge during the first subframe and the third phase portion of the charge during the second subframe.

33. The time-of-flight sensing system of claim 32,
wherein the first pixel circuit further comprises a second reset transistor coupled between the supply rail and the second floating diffusion, wherein the second reset transistor is configured to reset the second floating diffusion,
wherein the second pixel circuit further comprises a fourth reset transistor coupled between the supply rail and the fourth floating diffusion, wherein the fourth reset transistor is configured to reset the fourth floating diffusion.

34. The time-of-flight sensing system of claim 33,
wherein the first pixel circuit further comprises a second sample and hold transistor coupled between a second storage node and the second floating diffusion, wherein the second storage node is configured to store the second phase portion of the charge during the first subframe and the first phase portion of the charge during the second subframe from the second floating diffusion through the second sample and hold transistor,
wherein the second pixel circuit further comprises a fourth sample and hold transistor coupled between a fourth storage node and the fourth floating diffusion, wherein the fourth storage node is configured to store the fourth phase portion of the charge during the first subframe and the third phase portion of the charge during the second subframe from the fourth floating diffusion through the fourth sample and hold transistor.

35. The time-of-flight sensing system of claim 34,
wherein the first pixel circuit further comprises:
a second source follower transistor having a gate coupled to the second storage node; and
a second row select transistor coupled to the second source follower transistor,
wherein the second pixel circuit further comprises:
a fourth source follower transistor having a gate coupled to the fourth storage node; and
a fourth row select transistor coupled to the second source follower transistor.

36. The time-of-flight sensing system of claim 21, wherein the time-of-flight pixel array further comprises a plurality of pixel circuits, wherein each of the plurality of pixel circuits comprises:
one of the plurality of photodiodes;
one of the plurality of first transfer transistors coupled to said one of the plurality of photodiodes;
one of the plurality of second transfer transistors coupled to said one of the plurality of photodiodes;
one of the plurality of third transfer transistors coupled to said one of the plurality of photodiodes; and
one of the plurality of fourth transfer transistors coupled to said one of the plurality of photodiodes.

37. The time-of-flight sensing system of claim 36, wherein each of the plurality of pixel circuits further comprises:
a first floating diffusion coupled to said one of the plurality of first transfer transistors to receive the first phase portion of the charge during the first subframe and the second phase portion of the charge during the second subframe;
a second floating diffusion coupled to said one of the plurality of second transfer transistors to receive the second phase portion of the charge during the first subframe and the first phase portion of the charge during the second subframe;
a third floating diffusion coupled to said one of the plurality of third transfer transistors to receive the third phase portion of the charge during the first subframe and the fourth phase portion of the charge during the second subframe; and
a fourth floating diffusion coupled to said one of the plurality of fourth transfer transistors to receive the fourth phase portion of the charge during the first subframe and the third phase portion of the charge during the second subframe.

38. The time-of-flight sensing system of claim 37, wherein each one of the plurality of pixel circuits further comprises:
a first reset transistor coupled between a supply rail and the first floating diffusion, wherein the first reset transistor is configured to reset the first floating diffusion;
a second reset transistor coupled between the supply rail and the second floating diffusion, wherein the second reset transistor is configured to reset the second floating diffusion;
a third reset transistor coupled between the supply rail and the third floating diffusion, wherein the third reset transistor is configured to reset the third floating diffusion;
a fourth reset transistor coupled between the supply rail and the fourth floating diffusion, wherein the fourth reset transistor is configured to reset the fourth floating diffusion.

39. The time-of-flight sensing system of claim 38, wherein each one of the plurality of pixel circuits further comprises:
a first sample and hold transistor coupled between a first storage node and the first floating diffusion, wherein the first storage node is configured to store the first phase portion of the charge during the first subframe and the second phase portion of the charge during the second subframe from the first floating diffusion through the first sample and hold transistor;
a second sample and hold transistor coupled between a second storage node and the second floating diffusion, wherein the second storage node is configured to store the second phase portion of the charge during the first subframe and the first phase portion of the charge during the second subframe from the second floating diffusion through the second sample and hold transistor;
a third sample and hold transistor coupled between a third storage node and the third floating diffusion, wherein the third storage node is configured to store the third phase portion of the charge during the first subframe and the fourth phase portion of the charge during the second subframe from the third floating diffusion through the third sample and hold transistor; and
a fourth sample and hold transistor coupled between a fourth storage node and the fourth floating diffusion, wherein the fourth storage node is configured to store the fourth phase portion of the charge during the first subframe and the third phase portion of the charge during the second subframe from the fourth floating diffusion through the fourth sample and hold transistor.

40. The time-of-flight sensing system of claim 39, wherein each one of the plurality of pixel circuits further comprises:
a first source follower transistor having a gate coupled to the first storage node;
a first row select transistor coupled to a source of the first source follower transistor;
a second source follower transistor having a gate coupled to the second storage node;
a second row select transistor coupled to the second source follower transistor;
a third source follower transistor having a gate coupled to the third storage node;
a third row select transistor coupled to a source of the third source follower transistor;
a fourth source follower transistor having a gate coupled to the fourth storage node; and
a fourth row select transistor coupled to the second source follower transistor.
